(19) United States
(12) Patent Application Publication
(10) Pub. No.: US 2025/0316472 A1
(43) Pub. Date: Oct. 9, 2025

(54) PROTECTIVE LAYER FORMING METHOD AND WORKPIECE PROCESSING METHOD

(71) Applicant: DISCO CORPORATION, Tokyo (JP)

(72) Inventors: Hiroshi ONODERA, Tokyo (JP); Makoto SHIMOTANI, Tokyo (JP); Shun HAMAOKA, Tokyo (JP)

(21) Appl. No.: 19/093,830

(22) Filed: Mar. 28, 2025

(30) Foreign Application Priority Data
Apr. 4, 2024 (JP) 2024-060716
Apr. 4, 2024 (JP) 2024-060719

(51) Int. Cl. H01L 21/02; H01L 21/683

(52) U.S. Cl. CPC H01L 21/02096; H01L 21/6835; H01L 2221/68327

(57) ABSTRACT

A new technique for removing warping and undulations in the shape of a workpiece, and a new technique for protecting a surface of a workpiece having projections and depressions without using a soft film are proposed. A protective layer forming method includes the steps of: coating a front surface of a workpiece with a water-soluble resin; pressing a liquid resin that cures in response to an external stimulus with a surface of the water-soluble resin coating the front surface of the workpiece and a resin film; and applying an external stimulus to the pressed liquid resin to cure the liquid resin.

### BACKGROUND OF THE INVENTION

### Field of the Invention

The present invention relates to a protective layer forming method and a workpiece processing method.

### Description of the Related Art

Semiconductor device chips are essential components in a variety of electronic devices. Such chips are manufactured using disk-shaped workpieces made of semiconductors such as silicon (Si), silicon carbide (SiC), and gallium arsenide (GaAs).

A disk-shaped workpiece is generally cut from a cylindrical ingot using a blade saw, a wire saw, or the like. The shape of the workpiece cut out in this manner often includes an overall curvature (warping) and minute undulations.

For this reason, a workpiece cut out from an ingot is often flattened to remove any warping or undulations before it is used to manufacture semiconductor device chips.

As an effective method for removing warping or undulations in the shape of a workpiece, for example, a method is known in which a cured ultraviolet curable resin is provided on one side of the workpiece and then the other side of the workpiece is ground, as described in JP 2009-148866 A.

Also, for device chips to be used for electronic devices, it is known that back grinding is performed to grind and thin a substrate as a workpiece, on which multiple devices are arranged, from the back side, and the substrate is then divided into individual devices.

The back grinding of the workpiece is performed using a grinding apparatus. In the grinding apparatus, the front side of the workpiece is held on a chuck table with the back side exposed upward, and a grinding abrasive stone moving along an annular path is brought into contact with the back side of the workpiece to grind the workpiece.

At this time, patterns forming devices and wiring, for example, are arranged on the front side of the workpiece. To protect these patterns, a protective member, which includes a material layer and an adhesive layer, is attached in advance to the front surface of the workpiece.

Also, bumps may be formed on the front surface of the substrate as the workpiece in order to establish electrical contact with the device, and in some cases, the front surface of the substrate may have projections and depressions with height differences. In such devices having projections and depressions with height differences, the adhesive layer of the attached protective member alone is not enough to accommodate the projections and depressions of the surface, and the front surface held on the chuck table will not be flat.

In this case, the workpiece (substrate) is not supported uniformly on the chuck table when grinding is performed using the grinding apparatus. This has presented problems where back grinding fails to flatten the back surface, and cracking or chipping is caused.

One possible solution to these problems is to use a protective member with a thick adhesive layer that can adequately accommodate the projections and depressions of the front surface of the workpiece (substrate). However, in this case, there is a concern that a residue of the adhesive layer tends to remain on the projections and depressions when the protective member is peeled off from the substrate, possibly leading to defects in the device chips.

With regard to the above, JP 2017-50536 A, for example, discloses an application in which the front surface (device surface) of a workpiece (substrate) is protected in advance with a soft resin film, a liquid resin that cures in response to an external stimulus is supplied to the film, pressure is then applied through another protective film to cause the liquid resin to permeate the projections and depressions of the substrate, and the liquid resin is cured to form a protective layer.

In JP 2017-50536 A, a soft film is brought into close contact with the front surface of the workpiece (substrate) so as to conform to the projections and depressions of the surface of the substrate. The adhesive layer is not formed on the film at least in the region that is in close contact with the device formation region of the substrate, so that the device formation region of the substrate does not come into contact with the adhesive layer.

### SUMMARY OF THE INVENTION

However, in the method described in JP 2009-148866 A, the ultraviolet curable resin may remain on the surface of the workpiece during peeling. This may cause poor suction and fixation of the workpiece during back grinding, or cause workpiece cracking during grinding. Furthermore, a residue of the ultraviolet curable resin may cause contamination inside the apparatus.

Furthermore, when a soft film is used as in JP 2017-50536 A, the film needs to undergo steps such as heating and stretching (expansion) to bring the film into close contact with the front surface (device surface) of the substrate while conforming to the projections and depressions of the front surface of the workpiece (substrate).

In view of the above issues, the present invention proposes a new technique for removing warping and undulations in the shape of a workpiece, and a new technique for protecting a surface of a workpiece having projections and depressions without using a soft film.

The problem to be solved by the present invention has been described above, and the means for solving this problem are now described.

According to one aspect of the present invention, a protective layer forming method for forming a protective layer on a front surface of a workpiece is provided. The protective layer forming method includes the steps of: coating the front surface of the workpiece with a water-soluble resin; pressing a liquid resin that cures in response to an external stimulus with a surface of the water-soluble resin coating the front surface of the workpiece and a resin film; and applying an external stimulus to the pressed liquid resin to cure the liquid resin.

It is preferable to include the step of laying the film on a flat table and supplying the liquid resin to the film. It is desirable to include the step of supplying the liquid resin to the surface of the water-soluble resin coating the front surface of the workpiece. The front surface of the workpiece may be coated with the water-soluble resin by spin coating. The water-soluble resin coating the front surface of the workpiece preferably has a thickness of 5 μm or less.

According to one aspect of the present invention, a workpiece processing method for processing the workpiece on which a protective layer is formed by the above method is provided. The workpiece processing method includes the steps of: holding the film on a chuck table to expose a back surface of the workpiece and grinding the back surface of the workpiece; and peeling off the film, the cured liquid resin, and the water-soluble resin from the workpiece.

It is preferable to include the step of, after peeling off the film, the cured liquid resin, and the water-soluble resin from the workpiece, holding the back surface of the workpiece on a chuck table to expose the front surface of the workpiece and grinding the front surface of the workpiece. It is desirable to include the step of, after peeling off the film, the cured liquid resin, and the water-soluble resin from the workpiece, cleaning the front surface of the workpiece with water.

The present invention has the following advantageous effects. That is, according to one aspect of the present invention, a workpiece can be obtained in which warping and undulations are eliminated. Also, according to one aspect of the present invention, a surface of a workpiece including projections and depressions can be protected without using a soft film.

### BRIEF DESCRIPTION OF THE DRAWINGS

FIG. 1 is a diagram illustrating an outline of the configuration of a protective film forming apparatus;

FIG. 2 is a diagram illustrating steps constituting a first embodiment of the present invention;

FIGS. 3A and 3B are diagrams illustrating a first protective layer forming step;

FIGS. 4A and 4B are diagrams illustrating a resin supplying step;

FIGS. 5A and 5B are diagrams illustrating a pressing step;

FIGS. 6A and 6B are diagrams illustrating a second protective layer forming step;

FIGS. 7A and 7B are diagrams illustrating a first grinding step;

FIGS. 8A and 8B are diagrams illustrating a peeling step;

FIGS. 9A and 9B are diagrams illustrating a second grinding step;

FIG. 10 is a diagram illustrating an outline of the configuration of a protective film forming apparatus;

FIG. 11 is a diagram illustrating steps constituting a second embodiment of the present invention;

FIGS. 12A and 12B are diagrams illustrating a coating step;

FIG. 13 is a diagram illustrating an example of a workpiece having a front surface with projections and depressions;

FIGS. 14A and 14B are diagrams illustrating a resin supplying step;

FIGS. 15A and 15B are diagrams illustrating a pressing step;

FIGS. 16A and 16B are diagrams illustrating a curing step;

FIGS. 17A and 17B are diagrams illustrating a grinding step;

FIGS. 18A and 18B are diagrams illustrating a peeling step; and

FIGS. 19A and 19B are diagrams illustrating a water cleaning step.

### DESCRIPTION OF THE PREFERRED EMBODIMENTS

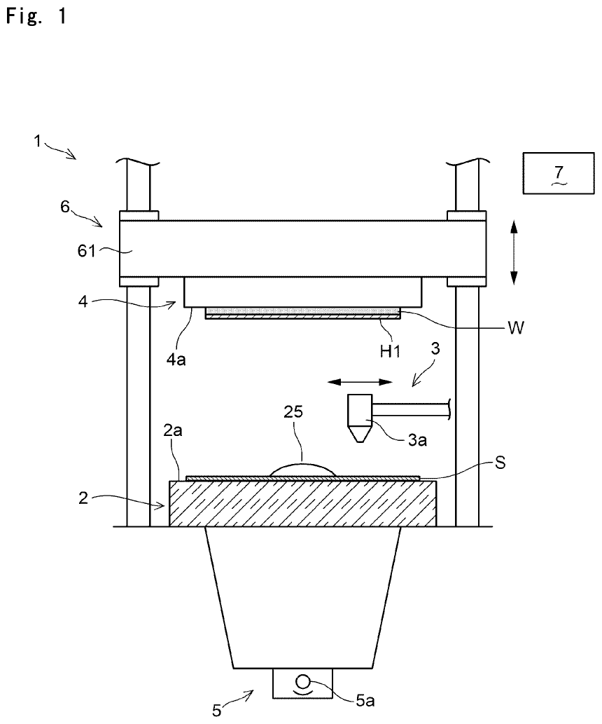

Referring to FIG. 1 to FIGS. 9A and 9B, a first embodiment is now described. FIG. 1 is a diagram illustrating an outline of the configuration of a protective film forming apparatus 1 used in a protective film forming method. FIG. 1 shows a state of the protective film forming apparatus 1 in which a first protective layer H1, which is made of a water-soluble resin and formed on a wafer as a workpiece W, faces a liquid resin 25 laid on the upper surface of a film S.

The protective film forming apparatus 1 includes a table 2 (lower surface plate), a holding means 4 (holding pad), a lifting and lowering means 6, an ultraviolet light application means 5, a liquid resin supply means 3, and a controller 7 for controlling various operating portions.

The table 2 has a horizontal upper surface 2a, is configured to transmit ultraviolet light, and is made of a transparent member such as glass, for example. A suction groove communicating with a suction source (not shown) is formed in the horizontal upper surface 2a. The upper surface 2a is configured to serve as a suction holding surface by creating a negative pressure on the upper surface 2a.

The holding means 4 (upper surface plate) is disposed above the horizontal upper surface 2a of the table 2. A suction groove communicating with a suction source (not shown) is formed in its horizontal lower surface 4a. The lower surface 4a is configured to serve as a suction holding surface by creating a negative pressure on the lower surface 4a. The lower surface 4a holds one side (upper surface) of the wafer as the workpiece W by suction, exposing the first protective layer H1 on the other side (lower surface).

The holding means 4 is fixed to the lower side of a lifting and lowering platform 61 of the lifting and lowering means 6, and moves up and down together with the lifting and lowering platform 61. The lifting and lowering means 6 has an actuator (not shown), and the lifting and lowering platform 61 is lifted and lowered by operating the actuator.

The ultraviolet light application means 5 is placed below the table 2 and has a light source 5a for emitting ultraviolet light. As will be described in detail below, the ultraviolet light passes through the table 2 and the film S and cures the liquid resin 25.

The liquid resin supply means 3 includes a supply nozzle 3a for supplying a liquid resin 25 in liquid state to the upper surface of the film S or the like laid on the table 2. The supply nozzle 3a is configured to be movable by an actuator (not shown), and may be positioned at a supply position where the supply nozzle 3a is aligned with the center position of the table 2, and at a retracted position where the supply nozzle 3a is farther from the table 2. The supply nozzle 3a is connected to a liquid resin supply source (not shown) and is capable of supplying a predetermined amount of liquid resin 25 to the upper surface of the film S.

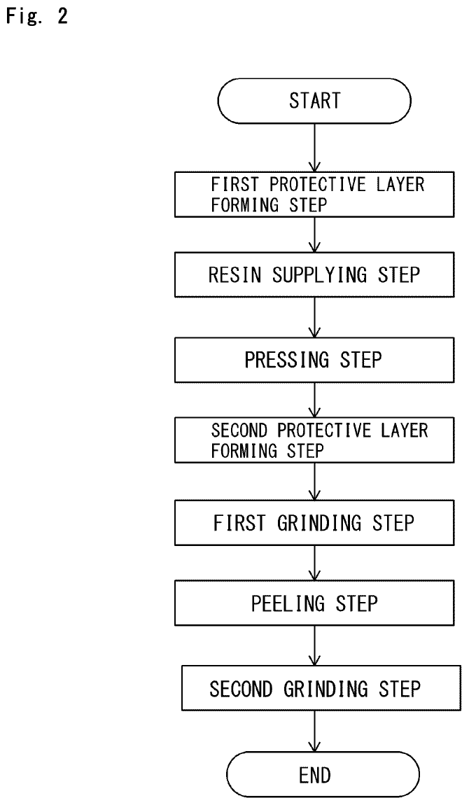

A protective layer forming method is now described that uses the protective film forming apparatus 1 configured as above. FIG. 2 is a diagram illustrating steps constituting the first embodiment of the present invention.

### First Protective Layer Forming Step

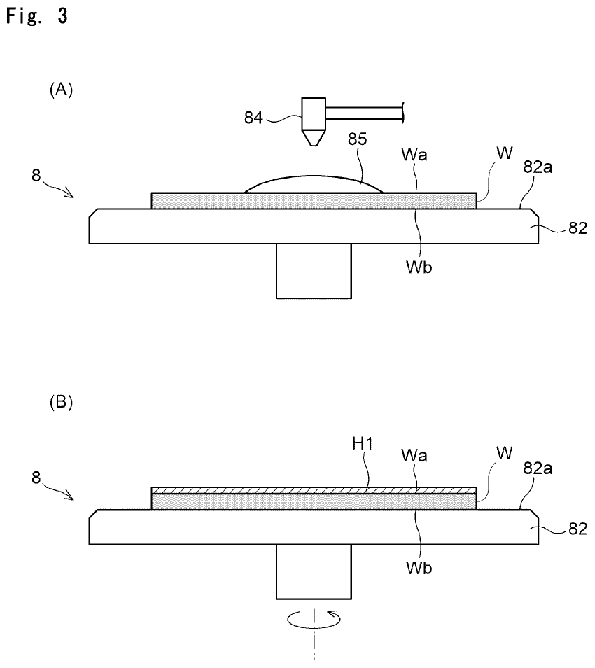

As shown in FIGS. 3A and 3B, the first protective layer forming step forms a first protective layer H1 made of a water-soluble resin on one side of a workpiece W.

Specifically, in a spin coating apparatus 8, the workpiece W is placed on a holding surface 82a of a rotation platform 82, which rotates in a horizontal plane, with the front surface Wa exposed. The rotation platform 82 is driven and rotated by a motor (not shown) to rotate the holding surface 82a at a predetermined rotation speed. The holding surface 82a is connected to a suction source (not shown). A negative pressure is created on the holding surface 82a, thereby holding the workpiece W by suction.

The workpiece W is configured to have the shape of a disk made of semiconductors such as silicon (Si), silicon carbide (Sic), and gallium arsenide (GaAs), and is cut out from a cylindrical ingot using a blade saw, wire saw, or the like. The front surface Wa and the back surface Wo of the workpiece W are formed with warping and undulations, and these warping and undulations are to be removed in a subsequent step.

Then, the water-soluble resin 85 is applied in droplets to the center of the front surface Wa of the rotating workpiece W from a supply nozzle 84, causing the water-soluble resin 85 to spread over the front surface Wa of the workpiece W by centrifugal force. This forms a first protective layer H1 made of the water-soluble resin 85 on the front surface Wa.

As the water-soluble resin 85 for forming the first protective layer H1, polyvinyl alcohol (PVA) or polyvinyl pyrrolidone (PVP) may be used, and a resin that can be easily dissolved and removed by water may be used, for example.

The thickness of the first protective layer H1 may be 5 μm or less, for example. As will be described below, the first protective layer H1 is to be removed, and serves to ensure removability in a subsequent peeling step. In terms of the amount of consumption of the first protective layer H1, it is preferable to limit the amount of consumption to 5 μm or less.

The formation of the first protective layer H1 described above is what is referred to as spin coating in which the water-soluble resin 85 is spread by centrifugal force to coat the front surface Wa of the workpiece W. After a predetermined time has passed since coating, the first protective layer H1 (water-soluble resin 85) adheres to the front surface Wa. Alternatively, it may be formed by other methods such as a casting method.

### Resin Supplying Step

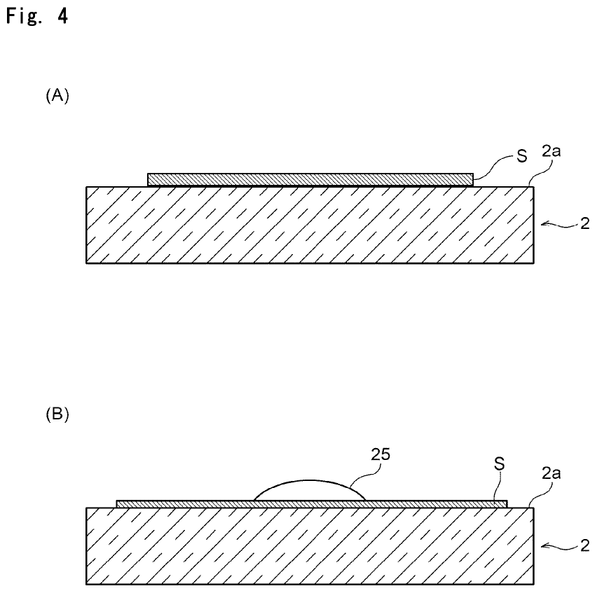

As shown in FIGS. 4A and 4B, the resin supplying step lays a resin film S on the flat table 2 in the protective film forming apparatus 1 (FIG. 1) and supplies a liquid resin 25, which cures in response to an external stimulus, to the film S.

Specifically, first, the resin film S is laid on the horizontal upper surface 2a of the table 2. The film S may be a film that is made of a transparent polyethylene terephthalate (PET) material that transmits ultraviolet light.

The film S may be circular, for example, and is configured to have a diameter larger than the front surface Wa of the workpiece W (first protective layer H1 (FIG. 3B)). Alternatively, the film S may have substantially the same shape as the upper surface 2a of the table 2 and cover substantially the entire area of the upper surface 2a. Alternatively, the film S may be rectangular in shape instead of circular.

As shown in FIG. 1, the supply nozzle 3a is positioned above a substantially central section of the film S, and the liquid resin 25 is applied from the supply nozzle 3a in droplets. A predetermined amount of liquid resin 25 is thus supplied to the upper surface 2a, resulting in the state shown in FIG. 4B. For example, the liquid resin 25 may be an ultraviolet curable resin, and “ResiFlat” (registered trademark) manufactured by DISCO Corporation may be used. The liquid resin 25 transmits ultraviolet light after curing.

### Pressing Step

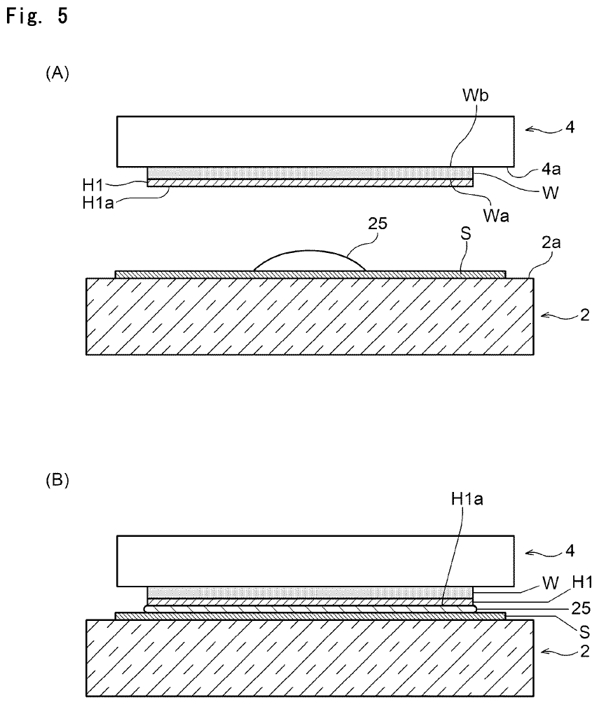

As shown in FIGS. 5A and 5B, the pressing step positions the first protective layer H1 facing the liquid resin 25 laid on the surface of the film S and presses the liquid resin 25.

Specifically, first, in FIG. 1, the supply nozzle 3a is retracted away from the position above the table 2. Then, as shown in FIG. 5A, the back surface Wb of the workpiece W is held by suction on the lower surface 4a of the holding means 4 to expose the first protective layer H1 downward, and the lifting and lowering means 6 (FIG. 1) lowers the workpiece W as shown in FIG. 5B. When the surface H1a of the first protective layer H1 reaches the liquid resin 25, the liquid resin 25 is pressed and spread between the first protective layer H1 and the film S without creating any gaps. As a result, a film of the liquid resin 25 is formed between the first protective layer H1 and the film S.

### Second Protective Layer Forming Step

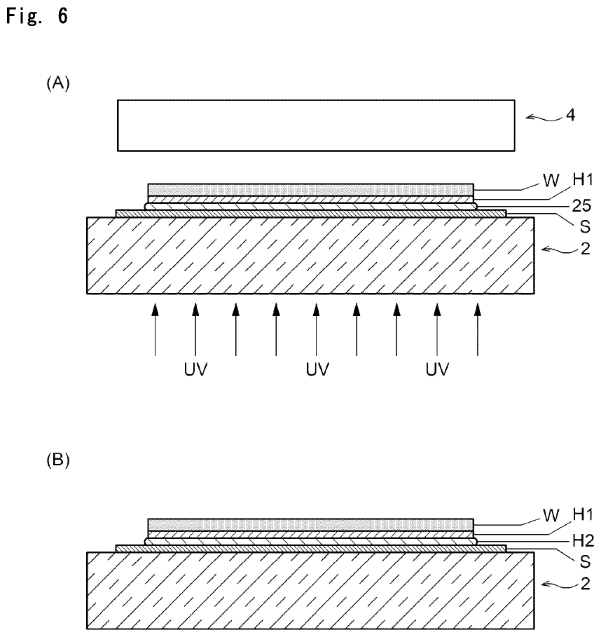

As shown in FIGS. 6A and 6B, the second protective layer forming step cures the liquid resin 25 by applying an external stimulus to the liquid resin 25, thereby forming a second protective layer H2.

Specifically, as shown in FIG. 6A, the holding of the workpiece W by suction is released, and the holding means 4 is retracted away from the workpiece W. Then, ultraviolet light UV is applied from below by the ultraviolet light application means 5 (FIG. 1), so that the ultraviolet light UV is applied to the liquid resin 25 through the table 2 to cure the liquid resin 25. As shown in FIG. 6B, the liquid resin 25 having a predetermined thickness is thus cured, forming a second protective layer H2.

In this embodiment, the external stimulus for curing the liquid resin 25 is application of ultraviolet light. However, other external stimulus such as heat may also be used. In this case, the liquid resin may be a thermosetting resin.

### First Grinding Step

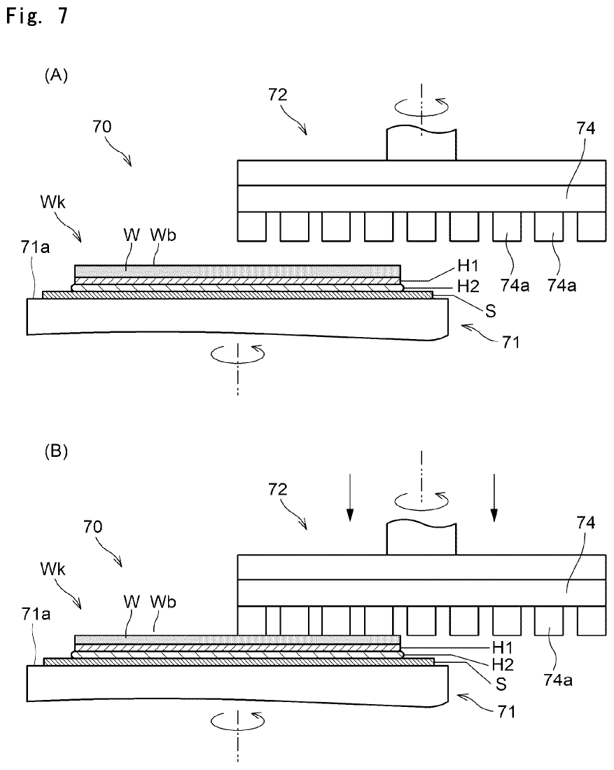

As shown in FIGS. 7A and 7B, the first grinding step treats, as a workpiece Wk of grinding processing, a composite member formed by integrating the film S, the second protective layer H2, the first protective layer H1, and the workpiece W, holds the film S on a chuck table 71 to expose the back surface Wb of the workpiece W, and grinds the back surface Wb of the workpiece W.

Specifically, the film S of the workpiece Wk is held by suction on the chuck table 71 of a grinding apparatus. Here, in the workpiece Wk, the film S, the second protective layer H2, the first protective layer H1, and the workpiece W are integrated, and the back surface Wb of the workpiece W is exposed.

The grinding apparatus 70 mainly includes the chuck table 71 and a grinding unit 72, and is configured to flatten the front surface Wa and the back surface Wb of the workpiece W by grinding.

The holding surface 71a of the chuck table 71 forms a horizontal surface, and a suction groove (not shown) is formed in its surface. A negative pressure is created in the suction groove to hold the film S on the holding surface 71a by suction. The chuck table 71 is configured to be rotated by a rotation mechanism (not shown).

The grinding unit 72 includes a grinding wheel 74 having multiple grinding abrasive stones 74a arranged spaced apart from one another in an annular shape. The grinding wheel 74 is rotated at a predetermined speed by a rotation mechanism (not shown), and is fed for grinding at a predetermined speed by a grinding feed mechanism (not shown).

By feeding the grinding unit 72 a predetermined distance, the back surface Wb of the workpiece W is flattened, eliminating any warping or undulations of the back surface Wb. After grinding, the back surface Wb of the workpiece W and the holding surface 71a of the chuck table 71 are parallel, and the back surface Wb of the workpiece W is horizontal.

### Peeling Step

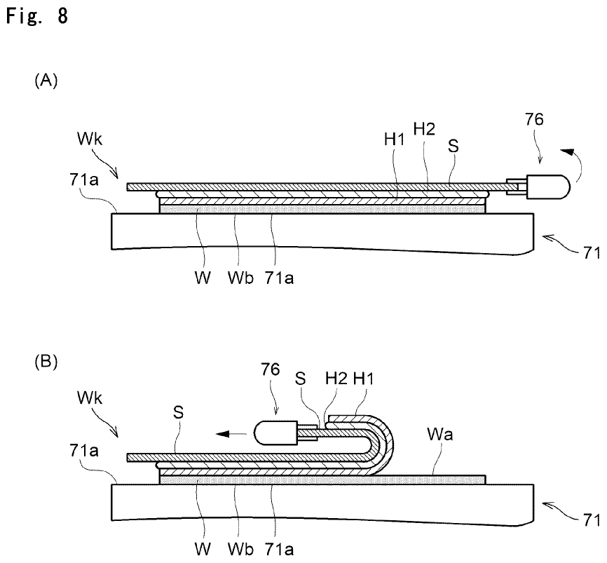

As shown in FIGS. 8A and 8B, the peeling step peels off the film S, the second protective layer H2, and the first protective layer H1 from the workpiece W.

Specifically, for example, the workpiece Wk that has been subjected to the first grinding step is inverted, and the back surface Wb of the workpiece W is held by suction on the holding surface 71a of the chuck table 71 to expose the film S upward, and an end of the film S is grasped by a clamp 76 and rolled up.

As a result, the film S, the second protective layer H2, and the first protective layer H1 are integrally peeled off from the workpiece W, exposing the front surface Wa of the workpiece W.

In this peeling, a part of the first protective layer H1 may remain on the front surface Wa of the workpiece W. However, this does not pose a problem because the first protective layer H1 is a water-soluble resin and is therefore removed by the grinding in the subsequent second grinding step or by the grinding water supplied to the processing point during grinding.

### Second Grinding Step

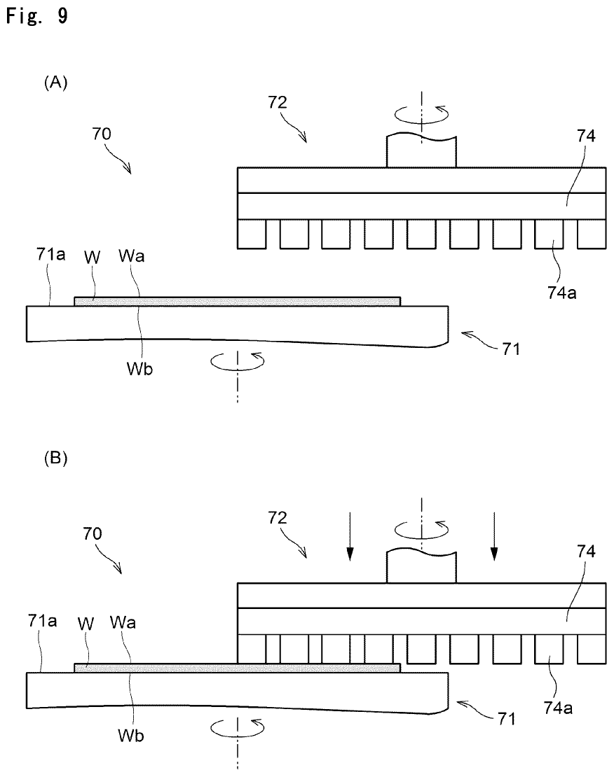

As shown in FIGS. 9A and 9B, the second grinding step holds the back surface Wb of the workpiece W that has been flattened on the chuck table 71 to expose the front surface Wa of the workpiece W, and grinds the front surface Wa of the workpiece W.

Specifically, the back surface Wb of the workpiece W that has been subjected to the peeling step and flattened is held by suction on the chuck table 71 of a grinding apparatus. This grinding apparatus may be the grinding apparatus used in the first grinding step, or a different grinding apparatus may also be used.

Then, by feeding the grinding unit 72 a predetermined distance, the front surface Wa of the workpiece W is flattened, eliminating any warping or undulations of the front surface Wa. Also, by the second grinding step, since the back surface Wb of the workpiece W has been flattened in advance, the front surface Wa of the workpiece W and the holding surface 71a of the chuck table 71 are parallel, and the front surface Wa of the workpiece W is horizontal after grinding.

In this manner, both the front surface Wa and the back surface Wb of the workpiece W are ground, and a workpiece W is obtained in which warping and undulations of both surfaces are eliminated. The first protective layer H1, which comes into contact with the workpiece W (front surface Wa), is made of a water-soluble resin 85. As such, even if the water-soluble resin 85 remains on the workpiece W (front surface Wa), it can be removed by the grinding water during grinding. This prevents the water-soluble resin 85 from remaining in the apparatus and contaminating the inside of the apparatus.

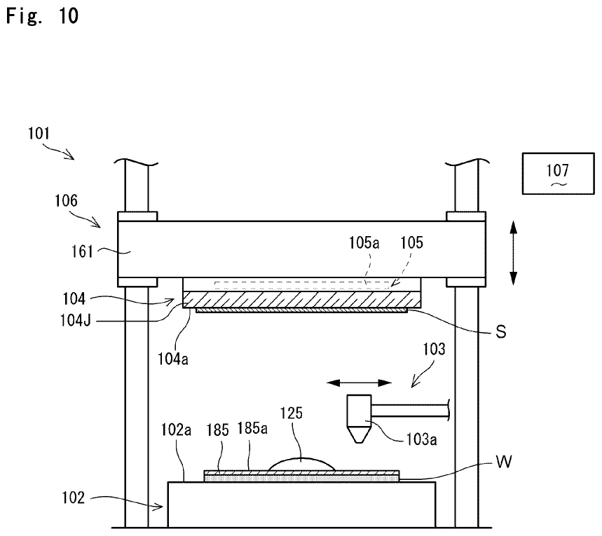

Referring to FIG. 10 to FIGS. 19A and 19B, a second embodiment of the present invention is now described. FIG. 10 is a diagram illustrating an outline of the configuration of a protective film forming apparatus 101 used in a protective film forming method. FIG. 10 shows a state of the protective film forming apparatus 101 in which a film S faces the workpiece W coated with a water-soluble resin 185.

The protective film forming apparatus 101 includes a table 102 (lower surface plate), a holding means 104 (holding pad), a lifting and lowering means 106, an ultraviolet light application means 105, a liquid resin supply means 103, and a controller 107 for controlling various operating portions.

The table 102 is configured to include a horizontal upper surface 102a. A suction groove communicating with a suction source (not shown) is formed in the horizontal upper surface 102a. The upper surface 102a is configured to serve as a suction holding surface by creating a negative pressure on the upper surface 102a.

The holding means 104 is fixed to the lower side of a lifting and lowering platform 161 of the lifting and lowering means 106, and moves up and down together with the lifting and lowering platform 161. The lifting and lowering means 106 has an actuator (not shown), and the lifting and lowering platform 161 is lifted and lowered by operating the actuator.

The holding means 104 includes an upper surface plate 104J having a horizontal lower surface 104a and an ultraviolet light application means 105 for applying ultraviolet light through the upper surface plate 104J.

The upper surface plate 104J is disposed above the horizontal upper surface 102a of the table 102 and is made of a transparent member such as glass, for example. A suction groove communicating with a suction source (not shown) is formed in the lower surface 104a of the upper surface plate 104J. The lower surface 104a is configured to serve as a suction holding surface by creating a negative pressure on the lower surface 104a. The lower surface 104a of the upper surface plate 104J holds the film S by suction. Also, as will be described in detail below, the lower surface 104a of the upper surface plate 104J functions as a flat pressing surface for pressing a liquid resin 125 through the film S.

The ultraviolet light application means 105 is configured to include a light source 105a that emits ultraviolet light, and is configured such that the ultraviolet light is transmitted through the upper surface plate 104J and applied to the lower side of the holding means 104. As will be described in detail below, the ultraviolet light emitted from the ultraviolet light application means 105 passes through the film S and cures the liquid resin 125.

The liquid resin supply means 103 is held by the table 102 (lower surface plate) and includes a supply nozzle 103a for supplying the liquid resin 125 in liquid state to the upper surface of the workpiece W coated with the water-soluble resin 185. The supply nozzle 103a is configured to be movable by an actuator (not shown), and may be positioned at a supply position where the supply nozzle 103a is aligned with the center position of the table 102, and at a retracted position where the supply nozzle 103a is farther from the table 102. The supply nozzle 103a is connected to a liquid resin supply source (not shown) and is capable of supplying a predetermined amount of liquid resin 125 to the upper surface of the workpiece W or the like.

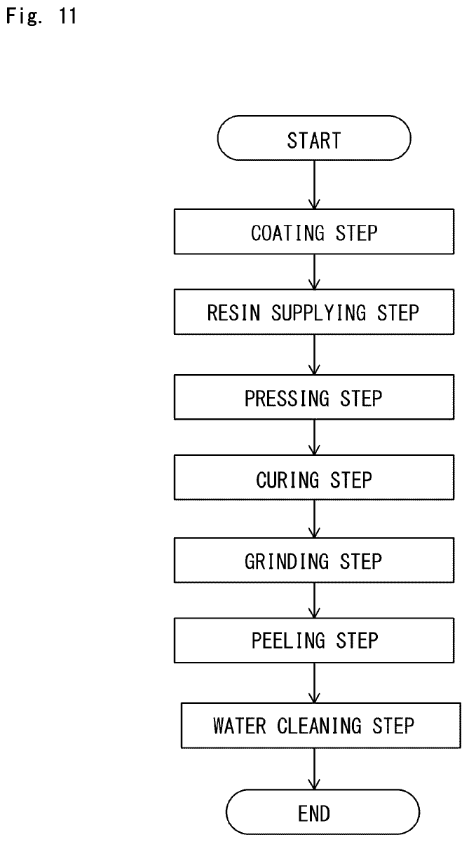

A protective layer forming method using the protective film forming apparatus 101 configured as above is now described. FIG. 11 is a diagram illustrating steps constituting a second embodiment of the present invention.

### Coating Step

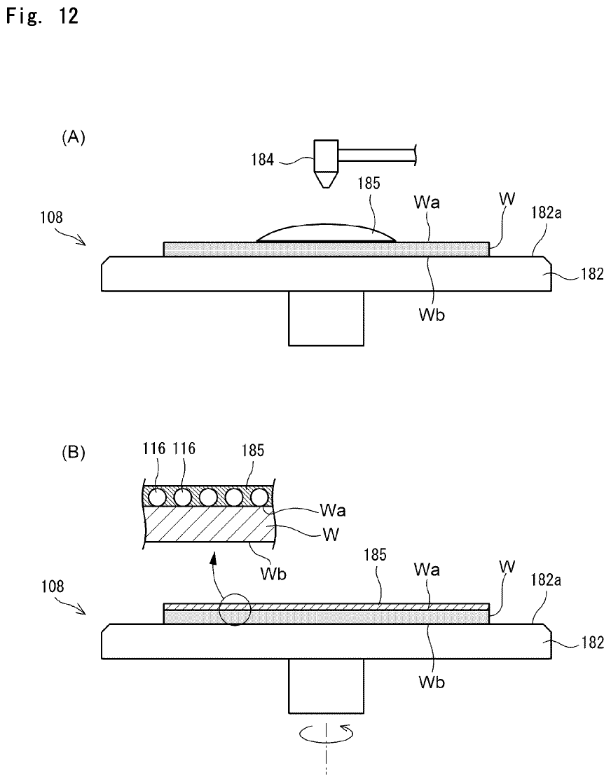

As shown in FIGS. 12A and 12B, the coating step coats the front surface Wa of the workpiece W with a water-soluble resin 185.

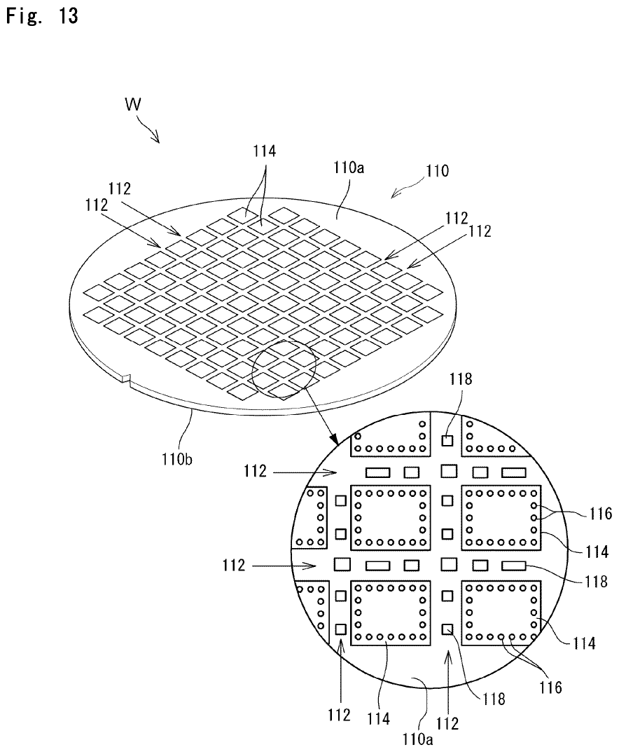

As shown in FIG. 13, in the workpiece W, devices 114 are formed in the respective regions defined by projected dicing lines 112, 112, which are set in a lattice pattern, on the front surface 110a of a disk-shaped wafer 110, which is made of semiconductors such as silicon (Si), silicon carbide (SiC), and gallium arsenide (GaAs), for example. Also, the devices 114 include bumps 116 (also referred to as high bumps) for establishing electrical contact of the devices 114. These bumps 116 create projections and depressions on the front surface of the wafer 110. In addition to the bumps 116, patterns such as TEG 118 may also create projections and depressions.

As shown in FIG. 12A, the workpiece W described above is placed, with the front surface Wa including projections and depressions exposed, on a holding surface 182a of a rotation platform 182, which rotates in a horizontal plane in a spin coating apparatus 108. The rotation platform 182 is driven and rotated by a motor (not shown) to rotate the holding surface 182a at a predetermined rotation speed. The holding surface 182a is connected to a suction source (not shown). A negative pressure is created on the holding surface 182a, thereby holding the workpiece W by suction.

Then, the water-soluble resin 185 is applied in droplets to the center of the front surface Wa of the rotating workpiece W from the supply nozzle 184, causing the water-soluble resin 185 to spread over the front surface Wa of the workpiece W by centrifugal force. The front surface Wa is thus coated with the water-soluble resin 185 as shown in FIG. 12B.

As the water-soluble resin 185, polyvinyl alcohol (PVA) or polyvinyl pyrrolidone (PVP) may be used, and a resin that can be easily dissolved and removed by water may be used, for example.

As shown in FIG. 12B, the water-soluble resin 185 covers the front surface Wa such that the gaps of the projections and depressions formed by the bumps 116 are filled with the water-soluble resin 185. When the water-soluble resin 185 covers the front surface Wa such that the projections and depressions are completely eliminated, the water-soluble resin 185 forms a protective layer. In this case, the thickness of the protective layer H can be set to 5 μm or less, for example. As will be described below, the water-soluble resin 185 is to be removed, and serves to ensure removability in a subsequent peeling step. In terms of the amount of consumption of the protective layer, it is preferable to limit the amount of consumption to 5 μm or less.

It should be noted that the water-soluble resin 185 may cover the front surface Wa such that the projections and depressions are completely eliminated after coating, but it may also cover the front surface Wa such that projections and depressions remain after coating.

The coating of the front surface Wa of the workpiece W with the water-soluble resin 185 is what is referred to as spin coating in which the water-soluble resin 185 is spread by centrifugal force to coat the front surface Wa of the workpiece W. After a predetermined time has passed since coating, the water-soluble resin 185 adheres to the front surface Wa. Alternatively, it may be formed by other methods such as a casting method.

### Resin Supplying Step

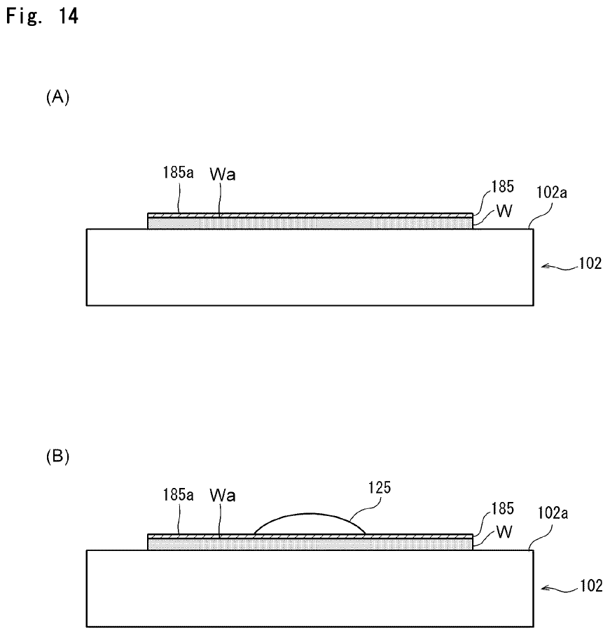

As shown in FIGS. 14A and 14B, the resin supplying step supplies a liquid resin 125, which cures in response to an external stimulus, to the surface 185a of the water-soluble resin 185 coating the front surface Wa of the workpiece W in the protective film forming apparatus 101 (FIG. 10).

Specifically, the workpiece W is transferred from the rotation platform 182 of the spin coating apparatus 108 (FIG. 12B), and the workpiece W is set on the table 102 such that the surface 185a of the water-soluble resin 185 is exposed as shown in FIG. 10. Then, the supply nozzle 103a is positioned above a substantially central section of the workpiece W, and the liquid resin 125 is applied from the supply nozzle 103a in droplets. A predetermined amount of liquid resin 125 is thus supplied to the front surface of the workpiece W covered with the water-soluble resin 185. For example, the liquid resin 125 may be an ultraviolet curable resin, and “ResiFlat” (registered trademark) manufactured by DISCO Corporation may be used. The liquid resin 125 transmits ultraviolet light after curing.

### Pressing Step

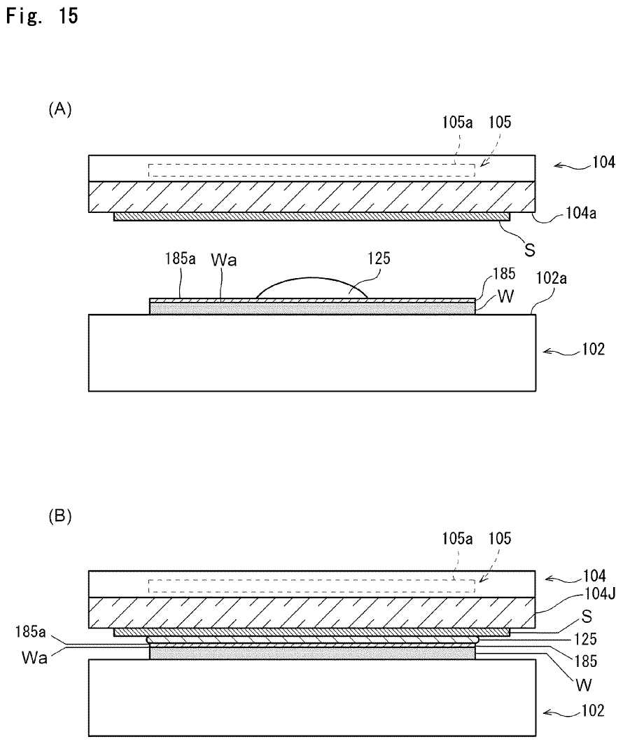

As shown in FIGS. 15A and 15B, the pressing step presses the liquid resin 125 supplied to the front surface of the workpiece with a flat pressing surface (the lower surface 104a of the upper surface plate 104J) through the film S so as to press and spread the liquid resin 125 between the film S and the workpiece W (the surface 185a of the water-soluble resin 185).

Specifically, first, the supply nozzle 103a (FIG. 10) is retracted away from the position above the table 102. Then, a resin film S is laid on the horizontal lower surface 104a of the upper surface plate 104J and held by suction so that the film S does not fall. The film S may be a film (sheet) that is made of a transparent polyethylene terephthalate (PET) material that transmits ultraviolet light.

The film S may be circular, for example, and is configured to have a diameter larger than the front surface Wa of the workpiece W covered with the water-soluble resin 185. Alternatively, the film S may have substantially the same shape as the lower surface 104a of the upper surface plate 104J and cover substantially the entire area of the lower surface 104a. Alternatively, the film S may be rectangular in shape instead of circular.

Then, the film S (upper surface plate 104J) is lowered by the lifting and lowering means 106 (FIG. 10). When the film S reaches the liquid resin 125, the liquid resin 125 spreads between the film S and the front surface Wa of the workpiece W coated with the water-soluble resin 185 (the surface 185a of the water-soluble resin 185) without creating any gaps.

### Curing Step

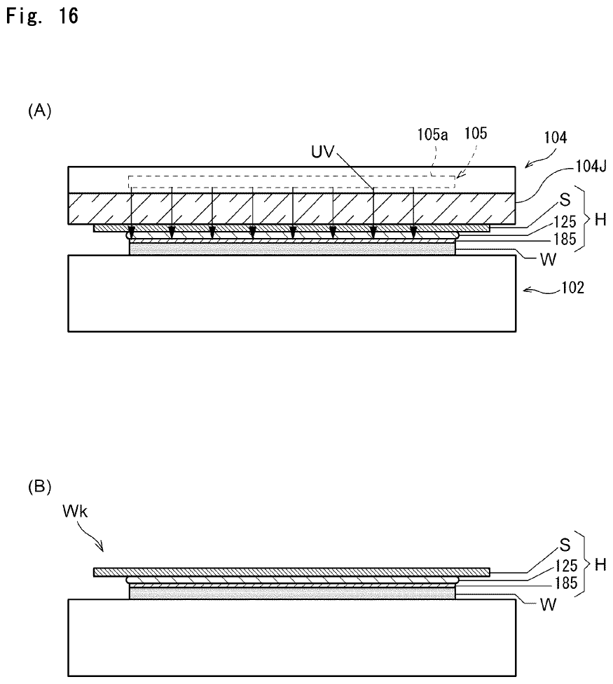

As shown in FIGS. 16A and 16B, the curing step cures the liquid resin 125 that has been pressed and spread in the pressing step and forms a protective layer H, which includes the film S, the cured liquid resin 125, and the water-soluble resin 185, on the front surface Wa of the workpiece W.

Specifically, with the liquid resin 125 pressed, the ultraviolet light application means 105 (FIG. 10) applies ultraviolet light UV to the liquid resin 125 from above through the film S to cure the liquid resin 125. This cures the liquid resin 125, forming the protective layer H including the film S, the cured liquid resin 125, and the water-soluble resin 185.

In this embodiment, the external stimulus for curing the liquid resin 125 is application of ultraviolet light. However, other external stimulus such as heat may also be used. In this case, the liquid resin may be a thermosetting resin.

### Grinding Step

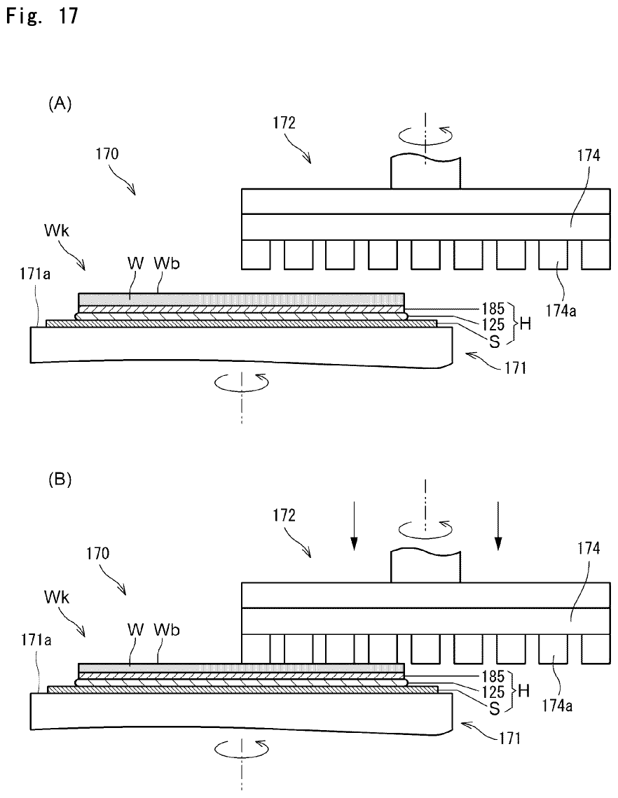

As shown in FIGS. 17A and 17B, the grinding step treats, as a workpiece Wk of grinding processing, a member formed by the method for forming the protective layer H described above, holds the film S on the chuck table 171 to expose the back surface Wb of the workpiece W, and grinds the back surface Wb of the workpiece W.

The grinding apparatus 170 mainly includes the chuck table 171 and a grinding unit 172, and is configured to flatten the back surface Wb of the workpiece W by grinding.

The holding surface 171a of the chuck table 171 forms a horizontal surface, and a suction groove (not shown) is formed in its surface. A negative pressure is created in the suction groove to hold the film S on the holding surface 171a by suction. The chuck table 171 is configured to be rotated by a rotation mechanism (not shown).

The grinding unit 172 includes a grinding wheel 174 having multiple grinding abrasive stones 174a arranged spaced apart from one another in an annular shape. The grinding wheel 174 is rotated at a predetermined speed by a rotation mechanism (not shown), and is fed for grinding at a predetermined speed by a grinding feed mechanism (not shown).

By feeding the grinding unit 172 a predetermined distance, the back surface Wb of the workpiece W is flattened, and the workpiece W is thinned.

### Peeling Step

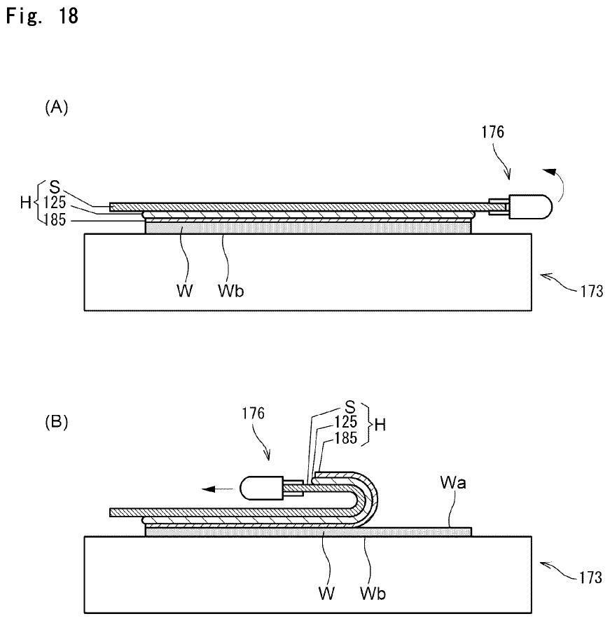

As shown in FIGS. 18A and 18B, the peeling step peels off the protective layer H from the workpiece W.

Specifically, for example, the workpiece Wk that has been subjected to the grinding step is inverted, and the back surface Wb of the workpiece W is held by suction on another holding table 173 to expose the film S upward, and an end of the film S is grasped by a clamp 176 and rolled up.

As a result, the protective layer H including the film S is peeled off from the workpiece W, exposing the front surface Wa of the workpiece W.

During this peeling, the water-soluble resin 185 that is a part of the protective layer H may remain in gaps of the projections and depressions of the front surface Wa of the workpiece W. However, since the residue is of the water-soluble resin 185, it can be easily removed by cleaning with water.

### Water Cleaning Step

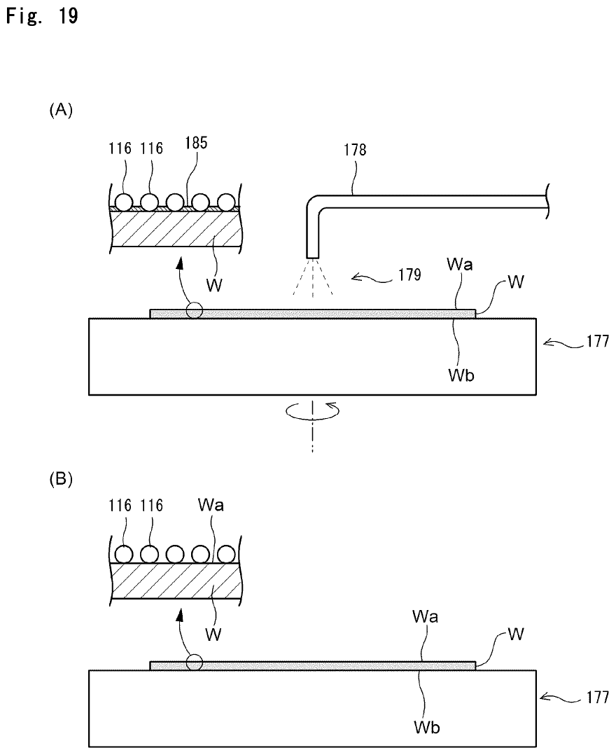

As shown in FIGS. 19A and 19B, taking into account the possibility of the presence of residue of the water-soluble resin 185 that is a part of the protective layer H, the peeling step may be invariably followed by a water cleaning step that cleans the front surface Wa of the workpiece W with water.

Specifically, in one example, the back surface Wb of the workpiece W is held by suction on a table 177 of a water cleaning apparatus while the table 177 is rotated to rotate the workpiece W, and water is sprayed toward the front surface Wa of the workpiece W from a water cleaning nozzle 178 to remove the water-soluble resin 185 remaining on the front surface Wa.

In this manner, a surface of the workpiece including projections and depressions can be protected without using a soft film. This allows for the omission of steps of heating and stretching (expanding) the film, for example, which would otherwise be needed if a soft film is used.

Additionally, the front surface Wa of the workpiece W that includes projections and depressions is coated with the water-soluble resin 185. As such, even if the water-soluble resin 185 remains on the workpiece W (front surface Wa) after the protective layer H is peeled off, the residue can be removed by the grinding water during grinding.

### REFERENCE SIGNS LIST

1 Protective film forming apparatus
2 Table
2a Upper surface
3 Liquid resin supply means
3a Supply nozzle
4 Holding means
4a Lower surface
5 Ultraviolet light application means
5a Light source
6 Lifting and lowering means
7 Controller
8 Spin Coating apparatus
25 Liquid resin
61 Lifting and lowering platform
70 Grinding apparatus
71 Chuck table
71a Holding surface
72 Grinding unit
74 Grinding wheel
74a Grinding abrasive stone
76 Clamp
82 Rotation platform
82a Holding surface
84 Supply nozzle
85 Water-soluble resin
H1 First protective layer
H1a Surface
H2 Second protective layer
S Film
UV Ultraviolet light
M Workpiece
Wa Front surface
Wb Back surface
Wk Workpiece
101 Protective film forming apparatus
102 Table
102a Upper surface
103 Liquid resin supply means
103a Supply nozzle
104 Holding means
104J Upper surface plate
104a Lower surface
105 Ultraviolet light application means
106 Lifting and lowering means
107 Controller
110 Wafer
110a Front surface
112 Projected dicing line
114 Device
116 Bump
125 Liquid resin
161 Lifting and lowering platform
170 Grinding apparatus
171 Chuck table
171a Holding surface
172 Grinding unit
173 Holding table
174 Grinding wheel
174a Grinding abrasive stone
176 Clamp
178 Water cleaning nozzle
182 Rotation platform
182a Holding surface
184 Supply nozzle
185 Water-soluble resin
185a Surface

What is claimed is:

1. A protective layer forming method for forming a protective layer on a front surface of a workpiece, the method comprising the steps of:
coating the front surface of the workpiece with a water-soluble resin;
pressing a liquid resin that cures in response to an external stimulus with a surface of the water-soluble resin coating the front surface of the workpiece and a resin film; and
applying an external stimulus to the pressed liquid resin to cure the liquid resin.

2. The protective layer forming method of claim 1, further comprising the step of laying the film on a flat table and supplying the liquid resin to the film.

3. The protective layer forming method of claim 1, further comprising the step of supplying the liquid resin to the surface of the water-soluble resin coating the front surface of the workpiece.

4. The protective layer forming method of claim 1, wherein the front surface of the workpiece is coated with the water-soluble resin by spin coating.

5. The protective layer forming method of claim 1, wherein the water-soluble resin coating the front surface of the workpiece has a thickness of 5 um or less.

6. A workpiece processing method for processing the workpiece on which a protective layer is formed by the method of claim 1, the workpiece processing method comprising the steps of:
holding the film on a chuck table to expose a back surface of the workpiece and grinding the back surface of the workpiece; and
peeling off the film, the cured liquid resin, and the water-soluble resin from the workpiece.

7. The workpiece processing method of claim 6, further comprising the step of, after peeling off the film, the cured liquid resin, and the water-soluble resin from the workpiece, holding the back surface of the workpiece on a chuck table to expose the front surface of the workpiece and grinding the front surface of the workpiece.

8. The workpiece processing method of claim 6, further comprising the step of, after peeling off the film, the cured liquid resin, and the water-soluble resin from the workpiece, cleaning the front surface of the workpiece with water.
